(19) United States
(12) Patent Application Publication
(10) Pub. No.: US 2025/0050863 A1
(43) Pub. Date: Feb. 13, 2025

(54) METHOD FOR DETERMINING AND RESETTING THE STATE OF CHARGE OF THE BATTERIES OF A HYBRID VEHICLE

(71) Applicant: RENAULT S.A.S., Boulogne Billancourt (FR)

(72) Inventors: Cedric CHANTREL, Guyancourt Cedex (FR); Samuel CREGUT, Guyancourt Cedex (FR); Laure DAGOUSSET, Guyancourt Cedex (FR); Christian HIRON, Guyancourt Cedex (FR); Claude LEHONGRE, Guyancourt Cedex (FR); Michel MENSLER, Guyancourt Cedex (FR); Alessandro MONTI, Guyancourt Cedex (FR)

(73) Assignee: RENAULT S.A.S., Boulogne Billancourt (FR)

(21) Appl. No.: 18/715,764

(22) PCT Filed: Nov. 18, 2022
(86) PCT No.: PCT/EP2022/082383

§ 371 Date: Oct. 30, 2024

(30) Foreign Application Priority Data
Dec. 8, 2021 (FR) FR2113122

(51) Int. Cl. B60W 20/13; G01R 31/3835; H02J 7/00; H02J 7/14; H02J 7/24; H02J 7/34

(52) U.S. Cl. CPC B60W 20/13; G01R 31/3835; H02J 7/007182; H02J 7/1423; H02J 7/24; H02J 7/342; B60W 2510/244; B60W 2710/06; B60W 2710/244

(57) ABSTRACT

A method is for determining and resetting the state of charge of at least one battery of a hybrid vehicle including a first battery, a second battery and a heat engine. The method includes, during a standby phase of the vehicle, a first step of charging the first battery via the second battery, during which: (i) the first battery is charged; (ii) the value of its voltage is measured; (iii) the value of the voltage of the first battery is compared with a threshold voltage value corresponding to a maximum state of charge of the first battery; and (iv) when the threshold voltage value is reached, stopping the charging of the first battery, determining that it is in a maximum state of charge and setting a value of its state of charge to maximum state of charge, and otherwise continuing to charge.

The invention relates to a method for determining and recalibrating the state of charge of the batteries of a hybrid vehicle.

In the non-limiting field of electric and hybrid vehicles, one of the main challenges of systems for managing traction batteries is estimation of the state of charge (SoC) of the battery. This information is displayed on the dashboard, in the form of a “battery gauge”, and allows the driver to see the range remaining. Since the range of an electric vehicle is less than that of an internal-combustion-engine vehicle, it is important to provide the driver with the most reliable information possible to reassure her or him. Errors in estimation of the battery gauge may lead the driver to find her-or himself in unpleasant situations (running out of fuel/charge) or even dangerous situations (lack of power during overtaking).

At the present time, the state of charge of a battery may be determined either by measuring voltage, or via a coulometric measurement, i.e. by counting the ampere-hours (Ah) entering and leaving the battery.

Moreover, future constraints on recycling will lead to elimination of heavy metals from vehicles and to replacement of current lead-acid batteries by lithium-ion batteries, and in particular by lithium-iron-phosphate batteries (LFP batteries).

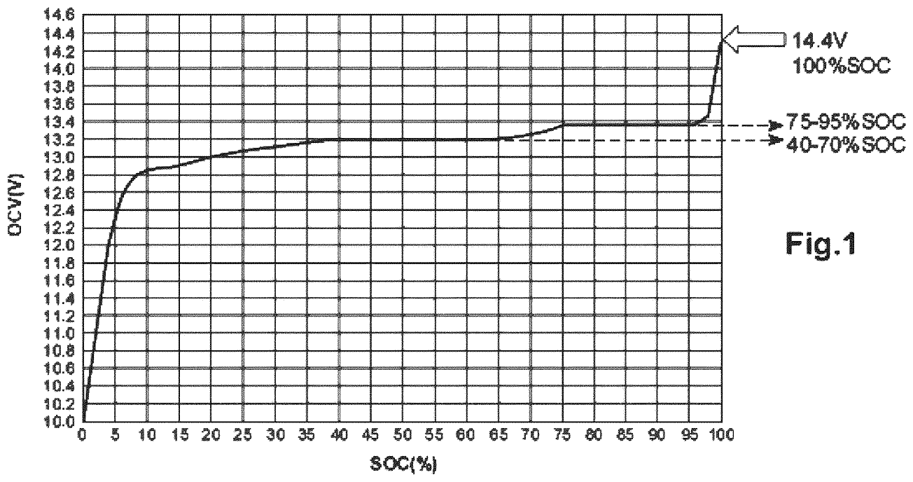

Now, lithium-ion batteries, and more particularly LFP batteries, have a curve of open-circuit voltage as a function of state of charge containing one or more plateaus, of the type shown in FIG. 1. Accurate determination of state of charge is then virtually impossible by measurement of voltage when the state of charge is level with these plateaus, i.e. between 40 and 70% and between 75and 95% for the battery in question in the example of FIG. 1.

Coulometric measurement, which is a method based on integration of current, is for its part by nature subject to drift, errors in measurement of current accumulating over time. This method therefore requires periodic recalibration via measurement of voltage. For batteries whose curve of voltage as a function of state of charge is of the type shown in FIG. 1, it is then necessary to almost completely recharge or discharge the battery in order to be able to take a voltage measurement in a region of the curve where state of charge may be accurately determined. This may be achieved in various ways depending on the type of vehicle.

Thus, when the vehicle is an all-electric vehicle or a “plug-in hybrid”, i.e. a vehicle rechargeable via the mains electricity grid, the two batteries of the vehicle (traction battery and auxiliary battery) may be recharged at the same time and recalibration may be performed when charging is almost complete.

In a hybrid vehicle (comprising a combustion engine, a traction battery and an auxiliary battery) or a “mild hybrid” vehicle (in which the batteries may be recharged while driving by harvesting the kinetic energy of braking), the batteries are recharged via the combustion engine while the vehicle is being driven. Recalibration of the state of charge of the batteries is then carried out while driving. In this phase of recharging/recalibrating while driving, it is not however possible to harvest the kinetic energy of braking, this preventing optimum management of the energy of the vehicle. In particular, when the two batteries are LFP batteries, it is possible to bring the auxiliary battery to a state of charge such that it may be gauged by measuring voltage. In contrast, to ensure optimum energy management, the traction battery must be located in plateau regions where voltage-based gauging is not possible because it is insufficiently accurate. There then remains only the coulometry-based method for determining state of charge, with the associated risks of drift. These risks of drift are currently compensated for by periodically recalibrating the traction battery by bringing it to a sufficiently high state of charge to allow accurate gauging by measuring the voltage. The recalibration is then carried out while driving, this complicating hybrid energy management, impacting the behavior of the automobile and increasing CO₂ footprint at the time of recalibration insofar as the kinetic energy of braking is then not used.

There is therefore a need for a method allowing the state of charge to be accurately determined and traction and auxiliary batteries to be recalibrated that does not disturb, or disturbs only little, management of the energy of the vehicle while driving.

Document WO201937012 A1 discloses a method for determining/recalibrating the state of charge of a battery when the vehicle is in a standby state. This method consists, with the vehicle being stopped and in the standby state, in measuring the voltage of the battery in two separate time intervals, then in using a correlation between the two voltage measurements having as parameter the open circuit voltage (OCV) of the battery. The OCV is then determined by a recursive least-squares algorithm. The state of charge is then determined depending on the OCV, for example via mapping or the like. This method for determining the state of charge thus uses relatively complex computations and may not always be reliable depending on the type of chemistry.

The present invention aims to remedy all or some of the aforementioned drawbacks.

To this end, a method is provided for determining and recalibrating the state of charge of at least one battery of a hybrid vehicle, the latter comprising a first battery, a second battery and a combustion engine, said method comprising, during a vehicle standby phase, a first step of charging the first battery by means of the second battery, in which step:
(i) the first battery is charged, in particular at a time t1,
(ii) the value of the voltage V1mes of the first battery is measured,
(iii) the value of the measured voltage V1mes is compared with a threshold voltage value V1threshmax corresponding to a maximum state of charge SOC1max of the first battery,
(iv) if the value of the measured voltage V1mes reaches said threshold voltage value V1threshmax, charging of the first battery is stopped, it is determined that the first battery is in a maximum state of charge SOC1max and a value of the state of charge SOC1 of the first battery is set to the value of the maximum state of charge SOC1max, otherwise, charging of the first battery is continued.

Thus, it is possible, at the end of the standby, to restart the vehicle with the gauge of at least one of the batteries recalibrated. By carrying out this recalibration outside of phases of driving the vehicle, it is possible to optimize management of the energy of the vehicle during driving phases, in a particularly simple manner.

However, in a standby phase, in the first charging step, it is possible for the state of charge of the second battery to be insufficient to allow the first battery to be charged to a maximum state of charge. Therefore, advantageously, during the first charging step:
in step (ii) the value of the voltage V2mes of the second battery is measured,
in step (iii), the value of the measured voltage V2mes is compared with a threshold voltage value V2threshmin corresponding to a minimum state of charge SOC2min of the second battery,
in step (iv) if the value of the measured voltage V2mes of the second battery reaches the threshold voltage value V2threshmin, it is determined that the second battery has reached a minimum state of charge SOC2min, charging of the first battery is stopped and a value of a state of charge SOC2 of the second battery is set to the value of the maximum state of charge SOC2min, otherwise, charging of the first battery is continued.

By thus monitoring the state of charge of the second battery, it will not be discharged beyond its capacity, this allowing its lifespan to be preserved and extended.

Once the first charging step has ended, either because the first battery has reached a maximum state of charge, or because the second battery has reached a minimum state of charge, the second battery may then be charged.

The method may thus advantageously comprise, during the same vehicle standby phase and after the first charging step, a second step of charging the second battery by means of the first battery, and, during this second step:
(i) the second battery is charged.

The second battery may then be charged until a vehicle driving phase and/or until it reaches a maximum or optimum state of charge, determined by monitoring the measured voltage across its terminals.

Thus, in one embodiment, in the second charging step:
(ii) the value of the voltage V2mes of the second battery is measured,
(iii) the value of the measured voltage V2mes is compared with a threshold voltage value V2threshmax corresponding to a maximum state of charge SOC2max of the second battery,
(iv) if the value of the measured voltage V2mes reaches said threshold voltage value V2threshmax, charging of the second battery is stopped, it is determined that the second battery is in a maximum state of charge SOC2max and a value of the state of charge SOC2 of the second battery is set to the value of the maximum state of charge SOC2max, otherwise charging of the second battery is continued.

This embodiment allows the gauge of the second battery to be recalibrated in the standby phase. It is particularly advantageous when the gauge of the first battery has itself been recalibrated in the first charging step, i.e. in the case where the second battery was charged sufficiently to allow the first battery to reach a maximum state of charge. Although not preferred, this embodiment could nevertheless also be envisioned in the case where, in the first charging step, the second battery reached a minimum state of charge preventing the gauge of the first battery from being recalibrated.

In this embodiment, the method may advantageously comprise, during the same vehicle standby phase and after the second charging step, a third step of charging the first battery by means of the second battery, in which:
(i) the first battery is charged,
(ii) the value of the voltage V1mes, V2mes of at least one of the two batteries is measured,
(iii) each measured voltage value V1mes, V2mes is compared with an optimum voltage value V1opt, V2opt corresponding to a state of charge of the battery that is optimum for a vehicle driving phase,
(iv) if at least one of the measured-voltage values V1mes, V2mes reaches said corresponding optimum voltage value, charging of the first battery is stopped, otherwise charging is continued.

This third step allows, in the next driving phase, the vehicle to be restarted under conditions that are optimum in respect of the charge of at least one of the two batteries. Generally, it will be chosen to place the second battery (typically the auxiliary battery) in an optimum state of charge.

In another embodiment, in the second charging step of the method according to the invention:
(ii) the value of the voltage V1mes, V2mes of at least one of the two batteries is measured,
(iii) each measured voltage value V1mes, V2mes is compared with an optimum voltage value V1opt. V2opt corresponding to a state of charge of the battery that is optimum for a vehicle driving phase
(iv) if at least one of the measured voltage values V1mes, V2mes reaches said corresponding optimum voltage value, charging of the second battery is stopped, otherwise charging is continued.

This embodiment is particularly advantageous in the case where, in the first charging step, the second battery reached a minimum state of charge that prevented the gauge of the first battery from being recalibrated (premature stoppage of the first charging step). Specifically, this makes it possible to avoid over discharging the first battery while simply settling for at least one of the batteries reaching a state of charge that is optimum for a driving phase. Generally, it will be chosen to place the second battery (typically the auxiliary battery) in an optimum state of charge. This embodiment is also envisionable in the case where the gauge of the first battery has itself been recalibrated in the first charging step, although this is not preferred.

Advantageously, the method according to the invention may comprise, during the same vehicle standby phase and immediately after the first or second charging step, in particular in which the value of the measured voltage of the battery being charged reached the threshold voltage value corresponding to a maximum state of charge, a step of balancing constituent cells of the battery charged during this first or second charging step. In this case, the subsequent charging step is carried out at the end of this balancing step.

In the case where, in the first or second charging step, the battery was unable to reach a maximum state of charge, either because the second battery was not sufficiently charged and reached a minimum (for the first battery) state of charge first, or because the standby phase ended before the first or second battery reached a maximum state of charge, provision may advantageously be made to charge this battery in the driving phase.

Thus, advantageously, the method according to the invention may comprise, in a vehicle driving phase immediately following said standby phase:
a step of comparing the current state-of-charge value of at least one of the batteries, or even of each of the batteries, with a predetermined threshold value,
when the current state-of-charge value of a battery is less than the threshold value, starting a step of charging this battery by means of the combustion engine of the vehicle, in which (i) said battery is charged, and, optionally:
   (ii) the value of the open-circuit voltage of said battery is determined,
   (iii) the determined open-circuit-voltage value is compared with a threshold voltage value corresponding to a maximum state of charge of said battery,
   (iv) if the determined open-circuit-voltage value reaches said threshold voltage value, charging of said battery is stopped, it is determined that said battery is in a maximum state of charge and a value of the state of charge of said battery is set to the value of the maximum state of charge, otherwise, charging of said battery is continued.

When the value of the current state of charge of each battery or of at least one of the batteries is greater than or equal to this threshold value, no charging action is initiated during driving. The energy management system of the vehicle may then be optimized.

Advantageously, the method according to the invention may give priority to the traction battery in order to ensure that its state of charge is always sufficient to ensure traction of the vehicle when the latter is started.

Thus, advantageously, in the method according to the invention, the first battery is a traction battery and the second battery is an auxiliary battery of the vehicle. Typically, the nominal voltage (average voltage in discharging phase) of a traction battery is greater than the nominal voltage of an auxiliary battery.

The invention also relates to a system comprising:
a first battery, in particular a traction battery, a second battery, in particular an auxiliary battery, and a combustion engine intended for a hybrid vehicle; and
a battery-management device,
   wherein the battery-management device is configured to determine and recalibrate the state of charge of at least one of said batteries using a method according to the invention.

Lastly, the invention relates to a hybrid vehicle comprising such a system.

The invention will now be described with reference to the, nonlimiting, appended drawings, in which:

FIG. 1 shows a curve plotting the open-circuit voltage (OCV) in volts as a function of the percentage state of charge SOC of an LFP battery.

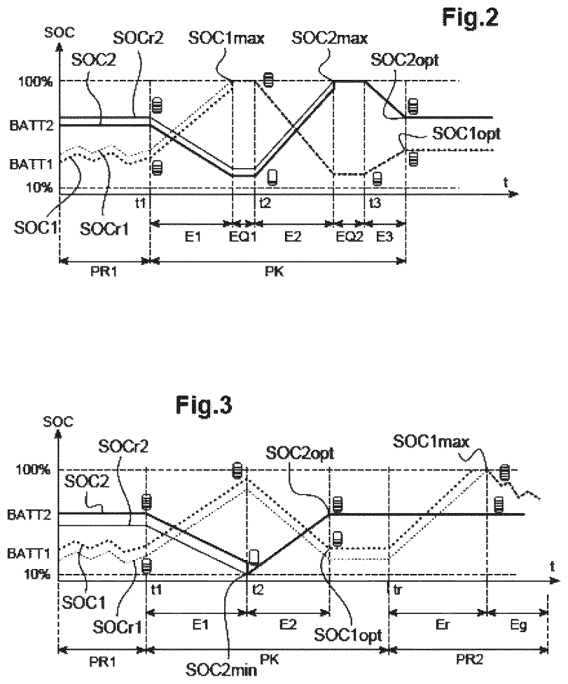

FIG. 2 schematically shows the state of charge of the batteries of a hybrid vehicle as a function of time according to one embodiment of a method according to the invention.

FIG. 3 schematically shows the state of charge of the batteries of a hybrid vehicle as a function of time according to another embodiment of a method according to the invention.

A hybrid vehicle typically comprises:
a traction battery, also called the high-voltage battery, intended to ensure traction of the vehicle. It is generally a battery with a nominal voltage of 48 V.
an auxiliary battery, also called a low-voltage battery, used to power electrical/electronic devices on board the vehicle. It is generally a battery with a nominal voltage of 12 V.
a combustion engine also intended to ensure traction of the vehicle.

In the method according to the invention, each of the traction and auxiliary batteries may be recharged either by the other battery in standby phase, or by the combustion engine in driving phase.

To this end, the batteries and the combustion engine are connected to a battery-management device configured to implement the method according to the invention. This management device typically comprises one or more processors (for example a microprocessor, a microcontroller or the like), in particular programmed to implement the method according to the invention. It may also comprise means of communication, optionally two-way communication, with the batteries, and voltage-measuring means. The one or more processors may comprise storage means which may be a random-access memory (RAM), an electrically erasable programmable read-only memory (EEPROM), a flash memory, an external memory or the like. These storage means may, inter alia, store received data, a control model, one or more maps and one or more computer programs. The management device for example forms part of, or forms, the battery management system (BMS) of the vehicle.

In FIGS. 2 and 3, BATT1 designates the traction battery and BATT2 designates the auxiliary battery of a hybrid vehicle. The solid curves represent the state of charge SOCi indicated by the gauge of battery i, and the dotted curves represent the real state of charge SOCri of battery i.

FIG. 2 illustrates one embodiment of the method according to the invention, in which the gauges of the two batteries are recalibrated. In this figure, the phase PR1 is a vehicle driving phase, in which the traction battery BATT1 undergoes successive charging and discharging, this charging for example corresponding to harvesting of the kinetic energy of braking, and the discharging corresponding to traction of the vehicle. The state of charge of the auxiliary battery BATT2 does not vary or hardly varies.

PK is a standby phase consecutive to the driving phase PR1. This standby phase PK may be detected by the management device in a conventional manner, based on parameters representative of the state of the vehicle (torque, etc.) received from suitable sensors. According to the invention, this standby phase PK is used to charge the batteries one after the other so that they reach a maximum state of charge in which the state of charge may be accurately determined based on the measured voltage, for any type of battery.

In this example, when a standby phase PK is detected, the management device triggers, at a time t1, a first charging step (denoted E1) in which (i) the traction battery is charged by means of the auxiliary battery. Since here the auxiliary battery is sufficiently charged, this first charging step E1 lasts until the traction battery reaches a maximum state of charge, at a time t1+Δt. To this end, the following steps will be reiterated: (ii) the value of voltage V1mes across the terminals of the traction battery is measured, (iii) the value of the measured voltage V1mes is compared with a threshold voltage value V1threshmax corresponding to a maximum state of charge SOC1max of the traction battery and (iv) if the value of the measured voltage V1mes reaches this threshold voltage value V1threshmax, charging of the traction battery is stopped, it is determined that the latter is in a maximum state of charge SOC1max and a value of the state of charge SOC1 of the traction battery is set to the value of the maximum state of charge SOC1max, otherwise, charging of the traction battery is continued.

A person skilled in the art will be able to determine the reiteration frequency depending on the type of battery. The value of the voltage V1mes measured across the terminals of the battery here corresponds to the open-circuit voltage, the vehicle being in a standby phase. The threshold voltage value V1threshmax and the corresponding maximum state of charge SOC1max may be determined by a person skilled in the art depending on the type of battery based on curves of the type shown in FIG. 1. The threshold voltage value V1threshmax and the value of the maximum state of charge SOC1max may be recorded in the management device, for example in the form of maps or curves of the type shown in FIG. 1.

At the end of the first charging step E1 (at a time t1+Δt), the traction battery is thus completely recharged and its gauge is recalibrated. It is then advantageously possible to rebalance the constituent cells of the traction battery in a balancing step EQ1. Such rebalancing is well known to those skilled in the art and will not be described in greater detail. It is typically carried out by means of suitable electronic components connected to the cells of the battery.

After this optional balancing step EQ1, the second charging step E2 is carried out at a time t2, and in this second charging step (i) the auxiliary battery is charged by means of the traction battery. This second charging step E2 lasts until the auxiliary battery reaches a maximum state of charge, at a time t2+Δt. To this end, the procedure is similar to that followed in the first step E1, the following steps being reiterated: (ii) the value of voltage V2mes across the terminals of the auxiliary battery is measured, (iii) the value of the measured voltage V2mes is compared with a threshold voltage value V2threshmax corresponding to a maximum state of charge SOC2max of the auxiliary battery and (iv) if the value of the measured voltage V2mes reaches the threshold voltage value V2threshmax, charging of the auxiliary battery is stopped, it is determined that it is in a maximum state of charge SOC2max and a value of the state of charge SOC2 of the auxiliary battery is set to the value of the maximum state of charge SOC2max, otherwise, charging of the auxiliary battery is continued.

This second charging step is thus entirely similar to the first charging step, the threshold voltage value and the value of the maximum state of charge being specific to the auxiliary battery.

At the end of this second charging step E2, it is also possible to carry out an optional step EQ2 of rebalancing the constituent cells of the auxiliary battery. After this optional rebalancing step EQ2, a third step E3 of charging the traction battery by means of the auxiliary battery will usually be carried out, in which step (i) the traction battery is charged, (ii) the value of the voltage of at least one of the two batteries V1mes, V2mes is measured, (iii) each measured voltage value V1mes, V2mes is compared with an optimum voltage value V1opt, V2opt corresponding to a state of charge SOC1opt, SOC2opt of the corresponding battery that is optimum for a vehicle driving phase, and (iv) if at least one of the measured voltage values V1mes, V2mes reaches the corresponding optimum voltage value, charging of the traction battery is stopped, otherwise charging is continued.

Thus, at the end of step E3, at a time t3+Δt, at least one of the batteries is, or indeed both batteries are, in a state of charge that is optimum for the next driving phase. These optimum states of charge may be determined by a person skilled in the art, depending on the type of battery and on the energy management of the vehicle in driving phase. A person skilled in the art may in particular choose to favor an optimum state of charge for the auxiliary battery or traction battery, or even both.

The whole process of determining and recalibrating the batteries thus ends, and the battery-management device waits for the next driving phase without triggering any other charging or discharging action.

FIG. 3 illustrates one embodiment of the method according to the invention, in which the gauge of the traction battery could not be recalibrated. In this figure, the phase PR1 is a vehicle driving phase similar to the one described with reference to FIG. 2. PK is a standby phase consecutive to the driving phase PR1 and PR2 is a driving phase consecutive to the parking phase PK.

FIG. 3 illustrates the case where the auxiliary battery is not sufficiently charged at the time when the vehicle is put on standby to allow the traction battery to be completely recharged. The first charging step E1 is then interrupted when, during monitoring of the value of the voltage of the auxiliary battery, the management device determines that the value of the voltage V2mes measured across the terminals of the auxiliary battery has reached a threshold voltage V2threshmin corresponding to a minimum state of charge SOC2min of the auxiliary battery. This is done by reiterating, in addition to steps (ii) to (iv) described above, measurement of the value of the voltage V2mes of the auxiliary battery and comparison of the measured value V2mes with the threshold voltage value V2threshmin, respectively, and requiring charging to stop when this threshold value is reached. The value of a state of charge SOC2 of the auxiliary battery is then set to the value of the maximum state of charge SOC2min. This amounts, in step (iv), to prioritizing the state of charge of the auxiliary battery. At the end of this first charging step, which nevertheless allowed the gauge of the auxiliary battery to be recalibrated, a second step E2 of charging the auxiliary battery with the traction battery is then advantageously carried out, at a time t2, until at least one of the batteries reaches an optimum state of charge SOC1opt, SOC2opt. This second charging step E2 is then similar to step E3 described with reference to FIG. 2. In general, in this second charging step E2, it is the auxiliary battery that is prioritized and the state of charge of which it is sought to optimize. The management device then waits for the next driving phase PR2. In this case, insofar as the traction battery is generally not in an optimum state of charge, a step Er of charging the traction battery not by means of the auxiliary battery but by means of the combustion engine of the hybrid vehicle is carried out at a time tr, and in particular at the start of the driving phase PR2. The value of the voltage of the traction battery is then monitored by reiterating steps (ii) to (iv) similar to those of the first step E1. It will be noted that in this case, the voltage measured across the terminals of the traction battery no longer corresponds to the open-circuit voltage across the terminals of the battery. It may then be necessary to determine the open-circuit voltage from the measured voltage, for example via modeling of the Kalman-filtering type, before comparing it with the value of the maximum threshold voltage. This threshold value may or may not be identical to the threshold value used in standby phase.

At the end of this recalibrating step performed while driving, at a time tr+Δt, the management device will be able to manage the energy of the hybrid vehicle optimally in a step Eg, in particular by recharging the traction battery by means of kinetic energy harvested while braking the vehicle.

Thus, in both cases (FIG. 2 and FIG. 3), the auxiliary battery, which ensures safe operation of the vehicle, will be charged when driving starts, unless the vehicle is started in the middle of the process.

In the latter case, charging of the auxiliary battery may be initiated in order to return it to its maximum state of charge as quickly as possible and meet the conditions of safety, for example at the start of the driving phase, by means of the combustion engine. It is then possible to proceed as described for the traction battery in step Er. In this case also, recalibration of the traction battery is triggered to recalibrate its gauge, even if it means degrading the optimization of energy management.

It will be noted that if one of the two batteries reaches, for example in two different standby phases, a minimum state of charge and a maximum state of charge, it is possible to determine its remaining capacity and to make provision, where appropriate, to perform a maintenance operation if this remaining capacity is judged to be too low, for example lower than a threshold value.

The method according to the invention thus allows, without requiring complex computations to be performed, accurate recalibration of battery gauges essentially in standby phase, so that in driving phase management of the energy of the vehicle is not disrupted.

1-10. (canceled)

11. A method for determining and recalibrating a state of charge of at least one battery of a hybrid vehicle, the vehicle comprising a first battery, a second battery, and a combustion engine, said method comprising:
charging, during a vehicle standby phase, the first battery via the second battery, the charging including:
(i) charging the first battery,
(ii) measuring a value of a voltage of the first battery,
(iii) comparing the value of the measured voltage with a first threshold voltage value corresponding to a maximum state of charge of the first battery,
(iv) when the value of the measured voltage reaches said first threshold voltage value, stopping the charging of the first battery, determining that the first battery is in the maximum state of charge, and setting a value of a state of charge of the first battery to the value of the maximum state of charge, and when the value of the measured voltage has not reached said first threshold voltage value, continuing the charging of the first battery.

12. The method as claimed in claim 11, wherein the charging the first battery includes:
in (ii), measuring a value of a voltage of the second battery,
in (iii), comparing the value of the measured voltage of the second battery with a second threshold voltage value corresponding to a minimum state of charge of the second battery,
in (iv), when the value of the measured voltage of the second battery reaches the second threshold voltage value, determining that the second battery has reached a minimum state of charge, stopping the charging of the first battery, and setting a value of a state of charge of the second battery to the value of the minimum state of, and when the value of the measured voltage of the second battery has not reached the second threshold voltage value, continuing the charging of the first battery.

13. The method as claimed in claim 11, further comprising, during the vehicle standby phase and after the charging of the first battery, charging the second battery via the first battery, and the charging the second battery includes:
(i) charging the second battery.

14. The method as claimed in claim 13, wherein the charging the second battery includes:
(ii) measuring the value of the voltage of the second battery,
(iii) comparing the value of the measured voltage of the second battery with a third threshold voltage value corresponding to a maximum state of charge of the second battery,
(iv) when the value of the measured voltage of the second battery reaches said third threshold voltage value, stopping the charging of the second battery, determining that the second battery is in a maximum state of charge, and setting a value of the state of charge of the second battery to the value of the maximum state of charge of the second battery, and when the value of the measured voltage of the second battery has not reached said third threshold voltage value, continuing the charging of the second battery.

15. The method as claimed in claim 14, further comprising, during the vehicle standby phase and after the charging of the second battery, charging the first battery via the second battery, including:
(i) charging the first battery.
(ii) measuring the value of the voltage of at least one of the two batteries is measured,
(iii) comparing each value of the measured voltage with an optimum voltage value corresponding to a state of charge of the battery that is optimum for a vehicle driving phase,
(iv) when at least one of the measured voltage values reaches said corresponding optimum voltage value, stopping the charging of the first battery, and when at least one of the measured voltage values has not reached said corresponding optimum voltage value, continuing said charging of the first battery.

16. The method as claimed in claim 13, wherein the charging the second battery includes:
(ii) measuring the value of the voltage of at least one of the two batteries.
(iii) comparing each measured voltage value with an optimum voltage value corresponding to a state of charge of the battery that is optimum for a vehicle driving phase,
(iv) when at least one of the measured voltage values reaches said corresponding optimum voltage value, stopping the charging of the second battery, and when at least one of the measured voltage values has not reached said corresponding optimum voltage value, continuing said charging of the second battery.

17. The method as claimed in claim 11, further comprising, during the vehicle standby phase and immediately after the charging the first battery, balancing constituent cells of the first battery charged during the charging the first battery.

18. The method as claimed in claim 14, further comprising, during the vehicle standby phase and immediately after the charging the second battery, balancing constituent cells of the second battery charged during the charging the second battery.

19. The method as claimed in claim 11, further comprising, in a vehicle driving phase immediately following said vehicle standby phase:
comparing a current state-of-charge value of a first battery with a predetermined threshold value,
when the current state-of-charge value of the first battery is less than the predetermined threshold value, starting charging the first battery via the combustion engine of the vehicle during which (i) said first battery is charged.

20. The method as claimed in claim 19, wherein the charging the first battery via the combustion engine includes:
(ii) determining a value of an open-circuit voltage of said first battery,
(iii) comparing the determined open-circuit-voltage value with a threshold voltage value corresponding to the maximum state of charge of said first battery,
(iv) when the determined open-circuit-voltage value reaches said threshold voltage value, stopping the charging of said first battery, determining that said first battery is in the maximum state of charge, and setting the value of the state of charge of said first battery to the value of the maximum state of charge, and, when the determined open-circuit-voltage value has not reached said threshold voltage value, continuing the charging of said first battery.

21. The method as claimed in claim 11, further comprising, in a vehicle driving phase immediately following said vehicle standby phase:
comparing a current state-of-charge value of a second battery with a predetermined threshold value,
when the current state-of-charge value of the second battery is less than the predetermined threshold value, starting charging the second battery via the combustion engine of the vehicle during which (i) said second battery is charged.

22. The method as claimed in claim 21, wherein the charging the second battery via the combustion engine includes:
(ii) determining a value of an open-circuit voltage of said second battery,
(iii) comparing the determined open-circuit-voltage value with a threshold voltage value corresponding to the maximum state of charge of said second battery.
(iv) when the determined open-circuit-voltage value reaches said threshold voltage value, stopping the charging of said second battery. determining that said second battery is in the maximum state of charge, and setting the value of the state of charge of said second battery to the value of the maximum state of charge, and, when the determined open-circuit-voltage value has not reached said threshold voltage value, continuing the charging of said second battery.

23. The method as claimed in claim 11, wherein the first battery is a traction battery and the second battery is an auxiliary battery of the vehicle.

24. A system comprising:
a first battery, a second battery, and a combustion engine configured for a hybrid vehicle; and
a battery-management device,
wherein the battery-management device is configured to determine and recalibrate a state of charge of at least one of said batteries according to the method as claimed in claim 11.
